(19) United States
(12) Patent Application Publication
(10) Pub. No.: US 2011/0006399 A1
(43) Pub. Date: Jan. 13, 2011

(54) SEMICONDUCTOR WAFER AND SEMICONDUCTOR WAFER MANUFACTURING METHOD

(75) Inventors: Tomoyuki Takada, Tsukuba-shi (JP); Sadanori Yamanaka, Tsukuba-shi (JP); Masahiko Hata, Tsuchiura-shi (JP); Taketsugu Yamamoto, Tsukuba-shi (JP); Kazumi Wada, Bunkyo-ku (JP)

Correspondence Address: SUGHRUE MION, PLLC, 2100 PENNSYLVANIA AVENUE, N.W., SUITE 800, WASHINGTON, DC, 20037, US

(73) Assignees: SUMITOMO CHEMICAL COMPANY, LIMITED, Chuo-ku, Tokyo (JP); THE UNIVERSITY OF TOKYO, Bunkyo-ku, Tokyo (JP)

(21) Appl. No.: 12/810,989

(22) PCT Filed: Dec. 26, 2008
(86) PCT No.: PCT/JP2008/004041

§ 371 Date: Oct. 4, 2010

(30) Foreign Application Priority Data
Dec. 28, 2007 (JP) 2007-341412

(51) Int. Cl. H01L 29/12; H01L 21/20

(52) U.S. Cl. 257/616; 438/479; 257/E29.068; 257/E21.09

(57) ABSTRACT

A high-quality GaAs-type crystal thin film using an inexpensive Si wafer with good thermal release characteristics is achieved. Provided is a semiconductor wafer comprising a single-crystal Si wafer; an insulating layer that has an open region and that is formed on the wafer; a Ge layer that is epitaxially grown on the wafer in the open region; and a GaAs layer that is epitaxially grown on the Ge layer, wherein the Ge layer is formed by (i) placing the wafer in a CVD reaction chamber that can create an ultra-high vacuum low-pressure state, (ii) performing a first epitaxial growth at a first temperature at which raw material gas can thermally decompose, (iii) performing a second epitaxial growth at a second temperature that is higher than the first temperature, (iv) performing a first annealing, at a third temperature that is loss than a melting point of Ge, on epitaxial layers formed by the first and second epitaxial growths, and (v) performing a second annealing at a fourth temperature that is lower than the third temperature. The Ge layer may he formed by repeating the first annealing and the second annealing a plurality of times, and the insulating layer may be a silicon oxide layer.

### TECHNICAL FIELD

The present invention relates to a semiconductor wafer and a method of manufacturing a semiconductor wafer. In particular, the present invention relates to a semiconductor wafer including a crystal thin film having good crystallinity formed on an inexpensive silicon wafer, and to a manufacturing method of such a semiconductor wafer.

### BACKGROUND ART

Various types of high-performance electronic devices are being developed that use heterojunctions in semiconductor devices therein made of compounds such as GaAs. Since the characteristics of these high-performance electronic devices are influenced by the quality of crystallinity, high quality crystal thin films are desired. The need for lattice matching at the heterointerfaces in thin film crystal growth of GaAs-based devices leads to the selection of wafers made of GaAs or of materials such as Ge whose lattice constant is very close to that of GaAs.

Non-Patent Document 1 discloses a technique for forming a high quality Ge epitaxial growth layer (sometimes referred to hereinafter as a “Ge epilayer”) on an Si wafer. With this technique, the Ge epilayer is formed in a limited region on the Si wafer, and cyclic thermal annealing is then performed on the Ge epilayer to achieve an average dislocation density of 2.3×10⁶ cm⁻².

Non-Patent Document 1: Hsin-Chian Luan et. al., “High-quality Ge Epilayers on Si with Low Threading-dislocation Densities” APPLIED PHYSICS LETTERS, Volume 75, No. 19, Nov. 8, 1999.

### DISCLOSURE OF THE INVENTION

### Problems to be Solved by the Invention

When manufacturing GaAs-type electronic devices, lattice matching is considered and a GaAs wafer or a wafer that can achieve lattice matching with GaAs, such as a Ge wafer, is selected, as described above. However, GaAs wafers or wafers that can achieve lattice matching with GaAs are expensive, and this increases the overall cost of the device. Furthermore, these wafers do not have sufficient heat dissipation characteristics, and this might result in limitations such as restrictions on the formation density of the devices in order to achieve a reliable thermal design or only using the devices in a temperature range for which thermal release can be achieved. Accordingly, there is a demand for a semiconductor wafer that can be manufactured using an inexpensive Si wafer with good thermal release characteristics and that has a high-quality GaAs-type crystal thin film. Therefore, it is an object of an aspect of the innovations herein to provide a semiconductor wafer, a method of manufacturing a semiconductor wafer, and an electronic device, which are capable of overcoming the above drawbacks accompanying the related art. The object can be achieved by combinations described in the independent claims. The dependent claims define further advantageous and exemplary combinations of the innovations herein.

### Means for Solving the Problems

To solve the above problems, according to a first aspect of the invention, provided is a semiconductor wafer comprising a single-crystal Si wafer; an insulating layer that has an open region and that is formed on the wafer; a Ge layer that is epitaxially grown on the wafer in the open region; and a GaAs layer that is epitaxially grown on the Ge layer, wherein the Ge layer is formed by (i) placing the wafer in a CVD reaction chamber that can create an ultra-high vacuum low-pressure state, (ii) performing a first epitaxial growth at a first temperature at which raw material gas can thermally decompose, (iii) performing a second epitaxial growth at a second temperature that is higher than the first temperature, (iv) performing a first annealing, at a third temperature that is less than a melting point of Ge, on epitaxial layers formed by the first and second epitaxial growths, and (v) performing a second annealing at a fourth temperature that is lower than the third temperature. The Ge layer may be formed by repeating the first annealing and the second annealing a plurality of times, and the insulating layer may be a silicon oxide layer.

According to a second aspect of the invention, provided is a semiconductor wafer comprising a single-crystal Si wafer; an insulating layer in which is formed an opening passing therethrough in a direction substantially perpendicular to a principal surface of the wafer, to expose the wafer; a Ge layer that is crystal-grown on the wafer within the opening; and a GaAs layer that is epitaxially grown on the Ge layer, wherein the Ge layer is formed by (i) placing the wafer in a CVD reaction chamber that can create an ultra-high vacuum low-pressure state, (ii) performing a first epitaxial growth at a first temperature at which raw material gas can thermally decompose, (iii) performing a second epitaxial growth at a second temperature that is higher than the first temperature, (iv) performing a first annealing, at a third temperature that is less than a melting point of Ge, on epitaxial layers formed by the first and second epitaxial growths, and (v) performing a second annealing at a fourth temperature that is lower than the third temperature.

In the above semiconductor wafer, the Ge layer may be formed by performing at least one of the first annealing and the second annealing in an atmosphere containing hydrogen. The Ge layer may be formed by being selectively crystal-grown within the opening using a CVD method including a raw material gas containing halogen atoms. Arithmetic mean roughness of the GaAs layer may he no greater than 0.02 μm. The insulating layer may be a silicon oxide layer. The insulating layer may include a plurality of the openings, and the semiconductor wafer may further comprise an adsorbing section that adsorbs raw material of the GaAs layer more quickly than a top surface of the insulating layer and that is arranged between one of the openings and another opening adjacent to the one of the openings.

The above semiconductor wafer may further comprise a plurality of the insulating layers; and an adsorbing section that adsorbs raw material of the GaAs layer more quickly than a top surface of any of the insulating layers and that is arranged between one of the insulating layers and another insulating layer that is adjacent to the one of the insulating layers. The adsorbing section may be a groove that reaches the wafer. Width of the groove may be between 20 μm and 500 μm, inclusive. The semiconductor wafer may comprise a plurality of the adsorbing sections, and the plurality of the adsorbing sections may be arranged at uniform intervals. Bottom area of the opening may be no greater than 1 mm². The bottom area of the opening may be no greater than 1600 μm². The bottom area of the opening may he no greater than 900 μm².

In the above semiconductor wafer, a bottom of the opening may be shaped as a rectangle, and a long side of the rectangle may be no greater than 80 μm. A bottom o f the opening may be shaped as a rectangle, and a long side of the rectangle may be no greater than 40 μm. The principal surface of the wafer may be a (100) surface, a bottom of the opening may be shaped as a square or a rectangle, and at least one side of the square or the rectangle is substantially parallel to a direction selected from a group including a <010> direction, a <0-10> direction, a <001> direction, and a <00-1> direction on the principal surface. The principal surface of the wafer is a (111) surface, a bottom of the opening is shaped as a hexagon, and at least one side of the hexagon is substantially parallel to a direction selected from a group including a <1-10> direction, a <-110>direction, a <0-11> direction, a <01-1> direction, a <10-1> direction, and a <101> direction on the principal surface. In the Miller index used to indicate a surface of a crystal or a direction, negative integers are usually represented by a bar over the number. However, in this Specification, negative integers are represented by a minus sign, for ease of explanation. For example, a surface that crosses values of 1, −2, and 3 respectively on an a-axis, a b-axis, and a c-axis in a unit grid is described as a (1-23) surface. Miller indices for directions are represented in the same way.

According to a third aspect of the invention, provided is a method of manufacturing a semiconductor wafer comprising forming an insulating layer on a single-crystal Si wafer; patterning the insulating layer to form an open region in the insulating layer that exposes the wafer; placing the wafer, on which the insulating layer having the open region is formed, in a CVD reaction chamber that can create an ultra-high vacuum low-pressure state; introducing a raw material gas into the CVD reaction chamber and heating the wafer to a first temperature at which the raw material gas can thermally decompose, to selectively form a first epitaxial layer made of Ge on a portion of the wafer exposed by the open region; introducing raw material gas into the CVD reaction chamber and heating the wafer to a second temperature that is higher than the first temperature, to form a second epitaxial layer made of Ge on the first epitaxial layer; annealing the first and second epitaxial layers at a third temperature that is lower than a melting point of Ge; annealing the first and second epitaxial layers at a fourth temperature that is lower than the third temperature; supplying a gas containing phosphine to a top surface of a Ge layer, after the annealing is performed, to surface process the Ge layer; and introducing a raw material gas for forming a GaAs layer into the CVD reaction chamber to epitaxially grow the GaAs layer on the top surface of the surface-processed Ge layer. The annealing at the third temperature and the annealing at the fourth temperature may be performed a plurality of times, and the insulating layer may be a silicon oxide layer.

According to a fourth aspect of the invention, provided is a method of manufacturing a semiconductor wafer comprising forming an insulating layer on a single-crystal Si wafer; patterning the insulating layer to form an opening in the insulating layer that exposes the wafer; placing the wafer, on which the insulating layer having the opening is formed, in a CVD reaction chamber that can create an ultra-high vacuum low-pressure state; introducing a raw material gas into the CVD reaction chamber and heating the wafer to a first temperature at which the raw material gas can thermally decompose, to selectively form a first epitaxial layer made of Ge on a portion of the wafer exposed by the opening; introducing raw material gas into the CVD reaction chamber and heating the wafer to a second temperature that is higher than the first temperature, to form a second epitaxial layer made of Ge on the first epitaxial layer; annealing the first epitaxial layer and the second epitaxial layer at a third temperature that is lower than a melting point of Ge; annealing the first epitaxial layer and the second epitaxial layer at a fourth temperature that is lower than the third temperature; supplying a gas containing phosphine to a top surface of a Ge layer, after the annealing is performed, to surface process the Ge layer; and introducing a raw material gas for forming a GaAs layer into the CVD reaction chamber to epitaxially grow the GaAs layer on the top surface of the surface-processed Ge layer.

In the above method of manufacturing a semiconductor wafer, at least one of the third temperature and the fourth temperature may he greater than or equal to 680° C. and less than 900° C. The annealing at the third temperature may include annealing the Ge layer in an atmosphere containing hydrogen. The annealing at the fourth temperature may include annealing the Ge layer in an atmosphere containing hydrogen. The selectively forming the first epitaxial layer made of Ge may include selectively crystal-growing the Ge layer in the opening according to a CVD method using a pressure between 0.1 Pa and 100 Pa, inclusive. The selectively forming the second epitaxial layer made of Ge may include selectively crystal-growing the Ge layer in the opening according to a CVD method using a pressure between 0.1 Pa and 100 Pa, inclusive.

In the above method of manufacturing a semiconductor wafer, the selectively forming the first epitaxial layer made of Ge may include selectively crystal-growing the Ge layer in the opening according to a CVD method performed in an atmosphere that includes raw material gas containing halogen atoms. The selectively forming the second epitaxial layer made of Ge may include selectively crystal-growing the Ge layer in the opening according to a CVD method performed in an atmosphere that includes raw material gas containing halogen atoms. The epitaxially growing the GaAs layer may include crystal-growing the GaAs layer with a growth speed no less than 1 nm/min and no greater than 300 nm/min.

### BRIEF DESCRIPTION OF THE DRAWINGS

FIG. 1 shows an exemplary cross-section of a semiconductor wafer 101 according to an embodiment of the present invention, along with HBTs formed on an element formation region.

FIG. 2 is an exemplary cross-sectional view of a step for manufacturing the semiconductor wafer 101.

FIG. 3 is an exemplary cross-sectional view of a step for manufacturing the semiconductor wafer 101.

FIG. 4 is an exemplary cross-sectional view of a step for manufacturing the semiconductor wafer 101.

FIG. 5 is an exemplary cross-sectional view of a step for manufacturing the semiconductor wafer 101.

FIG. 6 is an exemplary cross-sectional view of a step for manufacturing the semiconductor wafer 101.

FIG. 7 shows the cross-sectional shape of the Ge layer 120 that is not annealed.

FIG. 8 shows the cross-sectional shape of the Ge layer 120 that is annealed at 700° C.

FIG. 9 shows the cross-sectional shape of the Ge layer 120 that is annealed at 800° C.

FIG. 10 shows the cross-sectional shape of the Ge layer 120 that is annealed at 850° C.

FIG. 11 shows the cross-sectional shape of the Ge layer 120 that is annealed at 900° C.

FIG. 12 shows an average value of the thickness of the GaAs layers 124 in the First Embodiment.

FIG. 13 shows a variation coefficient of the thickness of the GaAs layers 124 in the First Embodiment.

FIG. 14 shows an average value of the thickness of the GaAs layers 124 in the Second Embodiment.

FIG. 15 shows an electron microscope image of a GaAs layer 124 in the Second Embodiment.

FIG. 16 shows an electron microscope image of a GaAs layer 124 in the Second Embodiment.

FIG. 17 shows an electron microscope image of a GaAs layer 124 in the Second Embodiment.

FIG. 18 shows an elect& microscope image of a GaAs layer 124 in the Second Embodiment.

FIG. 19 shows an electron microscope image of a GaAs layer 124 in the Second Embodiment.

FIG. 20 shows an electron microscope image of a GaAs layer 124 in the Third Embodiment.

FIG. 21 shows an electron microscope image of a GaAs layer 124 in the Third Embodiment.

FIG. 22 shows an electron microscope image of a GaAs layer 124 in the Third. Embodiment.

FIG. 23 shows an electron microscope image of a GaAs layer 124 in the Third Embodiment.

FIG. 24 shows an electron microscope image of a GaAs layer 124 in the Third Embodiment.

FIG. 25 shows an electron microscope image of a GaAs layer 124 in the Fourth Embodiment.

FIG. 26 shows an electron microscope image of a GaAs layer 124 in the Fourth Embodiment.

FIG. 27 shows an electron microscope image of a GaAs layer 124 in the Fourth Embodiment.

FIG. 28 shows an electron microscope image of the semiconductor wafer of the Fifth Embodiment.

FIG. 29 shows a laser microscope image of the HBT element of the Sixth Embodiment.

FIG. 30 shows a laser microscope image of the electronic clement of the Seventh Embodiment.

FIG. 31 shows a relationship between the electrical characteristics of HBT elements and the area of the open regions.

### LIST OF REFERENCE NUMERALS

101 Semiconductor wafer
102 Si wafer
104 Insulating layer
108 Collector electrode
110 Emitter electrode
112 Base electrode
120 Ge layer
124 GaAs layer
130 Silicon oxide film

### BEST MODE FOR CARRYING OUT THE INVENTION

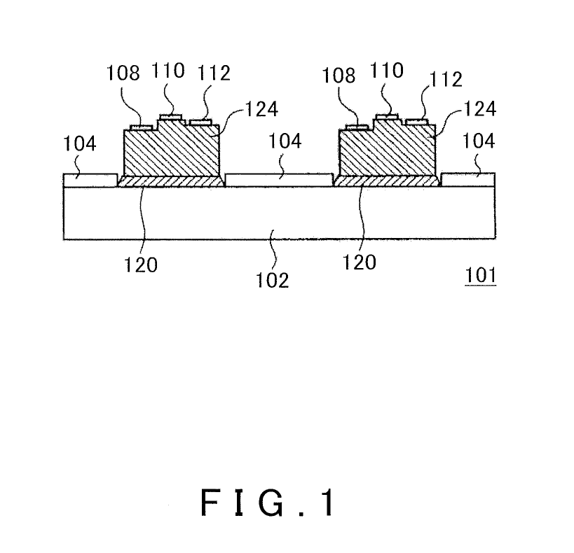

Hereinafter, some embodiments of the present invention will be described. The embodiments do not limit the invention according to the claims, and all the combinations of the features described in the embodiments are not necessarily essential to means provided by aspects of the invention. FIG. 1 shows an exemplary cross-section of a semiconductor wafer 101 according to an embodiment of the present invention, along with HBTs (Heterojunction Bipolar Transistors) formed on element formation regions. The semiconductor wafer 101 includes a single-crystal Si wafer 102, an insulating layer 104, Ge layers 120, and GaAs layers 124. The HBTs are formed as electronic elements on the GaAs layers 124.

A collector mesa, an emitter mesa, and a base mesa of an HBT are formed on the top surface of each GaAs layer 124. The collector electrode 108, the emitter electrode 110, and the base electrode 112 are formed on the top surfaces of the collector mesa, the emitter mesa, and the base mesa via contact holes. The collector layer, the emitter layer, and the base layer of an HBT are included in each GaAs layer 124.

One example of the collector layer is a layered thin film obtained by layering, in the stated order from the wafer, an n⁺GaAs layer with a carrier concentration of 3.0×10¹⁸ cm⁻³ and a thickness of 500 nm and an n⁻GaAs layer with a carrier concentration of 1.0×10¹⁶ cm⁻³ and a thickness of 500 nm. One example of the base layer is a p⁻GaAs layer with a carrier concentration of 5.0×10¹⁹ cm⁻³ and a thickness of 50 nm. One example of the emitter layer is a layered thin film obtained by layering, in the stated order from the wafer, an n⁻InGaP layer with a carrier concentration of 3.0×10¹⁷ cm⁻³ and a thickness of 30 nm, an n³⁰ GaAs layer with a carrier concentration of 3×10¹⁸ cm⁻³ and a thickness of 100 nm, and an n⁺InGaAs layer with a carrier concentration of 1.0×10¹⁹ cm⁻³ and a thickness of 100 nm.

The Si wafer 102 is an example of a single-crystal Si wafer. The Si wafer 102 may be a commercial Si wafer.

The insulating layer 104 is formed on the Si wafer 102, and includes open regions. The open regions may expose the Si wafer 102. The insulating layer 104 may be a silicon oxide layer, for example. The area of a single open region is no greater than 1 mm², for example, and is preferably no greater than 0.25 mm².

The insulating layer 104 has openings in the open regions. In this Specification, the “bottom shape” of the opening refers to the shape of the opening on a surface on the wafer side of the layer on which the opening is formed. The bottom shape of the opening may be referred to as the “bottom of the opening.” The “planar shape” of the covering region refers to the shape projected by the covering region onto the principal surface of the wafer. The area of the planar shape of the covering region may be referred to as the “area of the covering region.” The top surface of the Si wafer 102 is an example of a principal surface of the wafer.

The bottom area of the opening may he no greater than 0.01 mm², is preferably no greater than 1600 μm², and more preferably no greater than 900 μm². If this area is no greater than 0.01 mm², the amount of time necessary to anneal the Ge layer formed within the opening can be shortened in comparison to the time necessary when this area is greater than 0.01 mm². If there is a large difference between the thermal expansion coefficients of the functional layer and the wafer, it becomes easy for the thermal annealing to cause localized warping in the functional layer. In this case as well, the occurrence of crystal defects in the functional layer due to warping can be restricted by setting the bottom area of the opening to be no greater than 0,01 mm².

If the bottom area of the opening is no greater than 1600 μm², a high-performance device can be manufactured by using a functional layer formed within the opening. If this area is no greater than 900 μm², these devices can he manufactured with high yield.

Instead, the bottom area of the opening may be greater than or equal to 25 μm². If this area is less than 25 μm² and a crystal is epitaxially grown within the opening, the rate of this crystal growth is unstable and disorder in the shape is likely to occur. In addition, if this area is less than 25 μm², processing of the device becomes more difficult and the yield is decreased, which is unfavorable from an industrial viewpoint. The ratio of the bottom area of the opening to the area of the covering region may be no less than 0.01%. If this ratio is less than 0.01% and a crystal is grown within the opening, the rate of this crystal growth is unstable. When calculating the above ratio, if a plurality of openings are formed within one covering region, the bottom area of the opening refers to the total bottom area of the plurality of openings contained within the covering region.

If the shape of the bottom area of an opening is a square or a rectangle, the length of a side of the bottom area having such a shape may be no greater than 100 μm, preferably no greater than 80 μm, more preferably no greater than 40 μm, and even more preferably no greater than 30 μm. If the length of a side of the bottom area with such a shape is no greater than 100 μm, the amount of time necessary to anneal the Ge layer formed within the opening can be shortened in comparison to the time necessary when this length is greater than 100 μm. Even there is a large difference between thermal expansion coefficients of the functional layer and the wafer, the occurrence of crystal defects in the Functional layer can be restricted.

If the length of a side of the bottom area shape of the opening is no greater than 80 μm, a high-performance device can be formed by using a functional layer formed within the opening. If the length of a side of the bottom area shape is no greater than 40 μm, these devices can be manufactured with high yield. Here, if the bottom area shape of the opening is a rectangle, the “length of a side” referred to above may be the length of a long side.

One opening may be formed within one covering region. As a result, when a crystal is epitaxially grown within the opening, the rate of this crystal growth can be stabilized. Instead, a plurality of openings may he formed within one covering region. In this case, the openings are preferably arranged at uniform intervals. As a result, when a crystal is epitaxially grown within the opening, the rate of this crystal growth can be stabilized.

If the bottom area shape of an opening is a polygon, the orientation of at least one side of the polygon may be substantially parallel to one crystallographic surface orientation of the principal surface of the wafer. The crystallographic surface orientation may be selected such that a stable surface can be formed on a side of the crystal grown within the opening. Here, the term “substantially parallel” includes cases in which one side of the polygon is slightly skewed from being parallel with one crystallographic surface orientation of the wafer. This skew may be no greater than 5°. In this way, the disorder of the crystal can be restricted so that the crystal can be grown stably. As a result, the crystal can be grown easily and with an ordered shape, thereby achieving a high quality crystal.

The principal surface of the wafer may be the (100) surface, the (110) surface, the (111) surface, or any equivalent surface. The principal surface of the wafer may be skewed slightly from the crystallographic surface orientation described above. In other words, the wafer may have an of angle. This skew may be no greater than 10°. This skew is preferably between 0.05° and 6°, and more preferably between 0.3° and 6°. When growing a rectangular crystal within the opening, the principal surface of the wafer may be the (100) surface, the (110) surface, or any equivalent surface. As a result, the crystal can be easily formed to have a four-fold symmetric surface.

The following describes an example in which the insulating layer 104 is formed on the (100) surface of the top surface of the Si wafer 102, the open region is formed in the insulating layer 104 and has a bottom shape that is square or rectangular, and a Ge layer 120 and a GaAs layer 124 are Formed within the open region. In this case, at least one side of the bottom shape of the open region may be substantially parallel to one of the directions selected from a group including the <010> direction, the <0-10> direction, the <001> direction, and the <00-1> direction of the Si wafer 102. As a result, the side surfaces of the GaAs crystal can be stabilized.

The following describes another example in which the insulating layer 104 is formed on the (111) surface of the top surface of the Si wafer 102, the open region is formed in the insulating layer 104 and has a bottom shape that is hexagonal, and a Ge layer 120 and a GaAs layer 124 are formed within the open region. In this case, at least one side of the bottom shape of the open region may he substantially parallel to one of the directions selected from a group including the <1-10> direction, the <-110> direction, the <0-11> direction, the <01-1> direction, the <10-1> direction, and the <-101> direction of the Si wafer 102. As a result, the side surfaces of the GaAs crystal can be stabilized. The planar shape of the open region may he an equilateral hexagon. Similarly, instead of a GaAs crystal, a GaN crystal, which is a hexagonal crystal, can he formed.

A plurality of insulating layers 104 may be formed on the Si wafer 102. As a result, a plurality of covering regions are formed on the Si wafer 102. An adsorbing section that adsorbs the material of the Ge layer 120 or the GaAs layer 124 more quickly than the top surfaces of any of the insulating layers 104 may he disposed between one of the insulating layers 104 and another insulating layer 104 that is adjacent to the one insulating layer 104. Each of the insulating layers 104 may be surrounded by the adsorbing section. As a result, when a crystal is epitaxially grown within the opening, the rate of this crystal growth can be stabilized. The Ge layer and the functional layer are each an example of the crystal described above.

Each insulating layer 104 may include a plurality of openings. The adsorbing section may be included between one of the plurality of openings and another opening adjacent to this one opening. A plurality of the adsorbing sections may be arranged at uniform intervals.

The adsorbing section may be the top surface of the Si wafer 102. The adsorbing section may be a groove that reaches the Si wafer 102. The width of this groove may be between 20 μm and 500 μm. The adsorbing section may be arranged at uniform intervals. The adsorbing section may be a region in which crystal growth occurs.

With chemical vapor deposition (CVD) or vapor phase epitaxy (VPE) methods, a raw material gas including constituent elements of the thin film crystal being formed is provided on the wafer, and the thin film is formed by vaporizing the raw material gas or by a chemical reaction with the raw material gas on the top surface of the wafer. The raw material gas supplied in a reaction apparatus generates a reactive intermediate (sometimes referred to hereinafter as a “precursor”) through a vapor phase reaction. The generated reactive intermediate is diffused as a gas and adsorbed on the wafer surface. The reactive intermediate adsorbed on the wafer surface is diffused on the wafer surface and deposited as a solid film.

By arranging the adsorbing section between adjacent insulating layers 104 or by surrounding insulating layers 104 with the adsorbing section, the precursor diffused in the top surface of the covering region can be trapped, adsorbed, or held by the adsorbing section. As a result, when a crystal is epitaxially grown within the opening, the rate of this crystal growth can be stabilized. The precursor is an example of the raw material of the crystal.

In the present embodiment, a covering region with a prescribed size is arranged on the top surface of the Si wafer 102 to cover the top surface of the Si wafer 102. For example, when using the MOCVD method to grow the crystal within the open region, a portion of the precursor that has reached the top surface of the Si wafer 102 is grown as a crystal on the top surface of the Si wafer 102. By consuming a portion of the precursor on the top surface of the Si wafer 102 in this way, the crystal formed within the opening can be grown at a stable rate.

Other examples of the adsorbing section include semiconductor materials such as Si and GaAs. For example, by using methods such as ion plating or sputtering on the top surface of the insulating layer 104, the adsorbing section can be formed by depositing amorphous semiconductor material or a semiconductor polycrystal. The adsorbing section may be disposed between adjacent insulating layers 104, or may be included in the insulating layers 104. The same effect can be achieved by arranging a region in which diffusion of the precursor is inhibited between adjacent covering regions or by surrounding the covering regions with regions that inhibit diffusion of the precursor.

If adjacent insulating layers 104 are only slightly separated, the rate of the crystal growth can be stabilized. The distance between adjacent insulating layers 104 may be no less than 20 μm. As a result, the rate of the crystal growth can be stabilized. Here, the distance between adjacent insulating layers 104 refers to the shortest distance between a point on the periphery of an insulating layer 104 and a point on the periphery of an adjacent insulating layer 104. The plurality of insulating layers 104 may be arranged at uniform intervals. In particular, if the distance between adjacent insulating layers 104 is loss than 10 μm, the rate of the crystal growth within the opening can be stabilized by arranging the insulating layers 104 at uniform intervals.

The Si wafer 102 may be a high-resistance wafer that does not include impurities, or may be a low-resistance wafer or mid-resistance wafer that includes positive or negative impurities. The Ge layer 120 may be Ge that does not include impurities, or may be Ge that includes positive or negative impurities.

The Ge layer 120 is epitaxially grown on the Si wafer 102 in an open region. The Ge layer 120 may be selectively epitaxially grown on the Si wafer 102 in an open region. The Ge layer 120 may he formed by undergoing annealing after being epitaxially grown, as described below.

Specifically, a wafer is placed in a CVD reaction chamber that can create an ultra-high vacuum low-pressure state, a first epitaxial growth is performed at a first temperature at which raw material gas can thermally decompose, and then a second epitaxial growth is performed at a second temperature that is higher than the first temperature. Next, a first annealing is performed, at a third temperature that is less than a melting point of Ge, on the epitaxial layers resulting from the first and second epitaxial growths, and then a second annealing is performed at a fourth temperature that is lower than the third temperature. The first annealing and the second annealing can be repeated multiple times. After annealing the Ge layer 120, a gas including phosphine may be supplied to the top surface of the Ge layer 120 for surface processing.

The Ge layer 120 may be annealed at a temperature below 900° C., preferably 850° C. or lower. As a result, the top surface of the Ge layer 120 can be kept flat. The flatness of the top surface of the Ge layer 120 is particularly important when forming another layer on the top surface of the Ge layer 120. The Ge layer 120 may be annealed at a temperature of 680° C. or higher, preferably 700° C. or higher. As a result, the density of the crystal defects in the Ge layer 120 can be decreased. The Ge layer 120 may be annealed at a temperature that is greater than or equal to 680° C. and below 900° C.

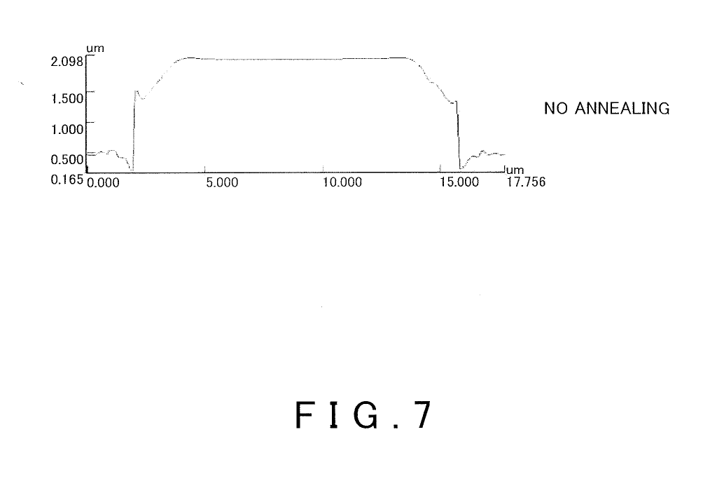

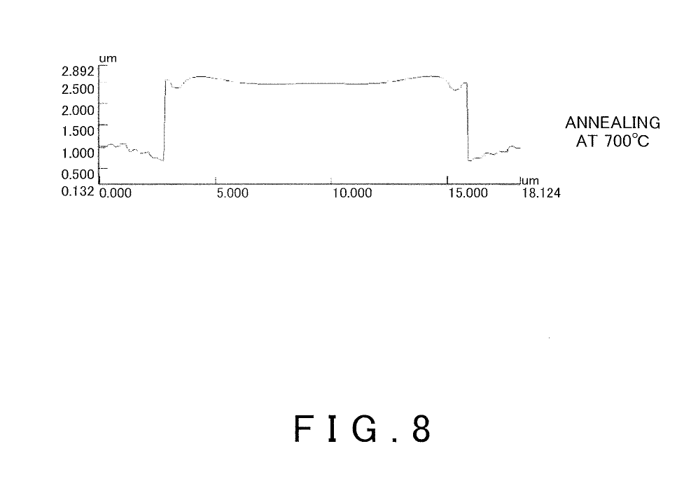

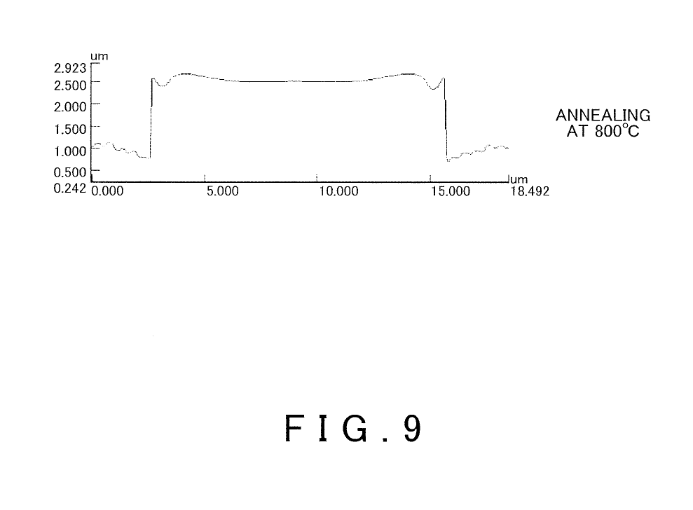

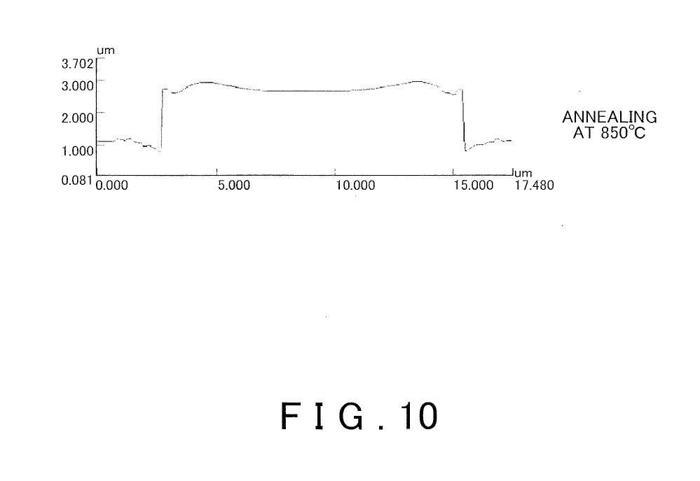

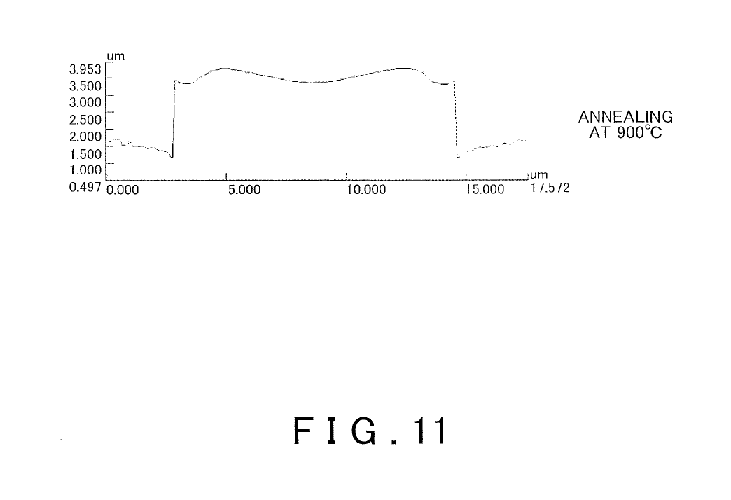

FIGS. 7 to 11 show a relationship between the annealing temperature and the flatness of the Ge layer 120. FIG. 7 shows the cross-sectional shape of the Ge layer 120 that is not annealed. FIGS. 8 to 11 respectively show cross-sectional shapes of a Ge layer 120 after being annealed at temperatures of 700° C., 800° C., 850° C., and 900° C. The cross-sectional shape of the Ge layer 120 can be observed by a laser microscope. The vertical axis in each of these Figures represents the distance in a direction perpendicular to the principal surface of the Si wafer 102, and shows the thickness of the Ge layer 120. The horizontal axis in each of these Figures represents the distance in a direction parallel to the principal surface of the Si wafer 102.

In each of these Figures, the Ge layer 120 was formed according to the following steps. First, the thermal oxidation method was used to form the insulating layer 104 as an SiO₂ layer on the top surface of the Si wafer 102, and the covering region and the open region were formed on the insulating layer 104. The Si wafer 102 was a commercial single-crystal Si wafer. The planar shape of the covering region was a square in which each side had a length of 400 μm. Next, the CVD method was used to selectively grow the Ge layer 120 within the open region.

Based on FIGS. 7 to 11, it is understood that lower annealing temperatures lead to favorable flatness of the top surface of the Ge layer 120. The top surface of the Ge layer 120 exhibits especially good flatness when the annealing temperature is below 900° C.

The Ge layer 120 may be annealed in an ambient atmosphere, a nitrogen atmosphere, an argon atmosphere, or a hydrogen atmosphere. In particular, by annealing the Ge layer 120 in an atmosphere that includes hydrogen, the top surface of the Ge layer 120 can be maintained in a smooth state while decreasing the density of crystal defects in the Ge layer 120.

The Ge layer 120 may be annealed with a temperature and duration that enables movement of crystal detects. The crystal defects in the Ge layer 120 move within the Ge layer 120 during the annealing, and are trapped in the interface between the Ge layer 120 and the insulating layer 104, in the top surface of the Ge layer 120, or in a gettering sink within the Ge layer 120, for example. As a result, the crystal defects near the top surface of the Ge layer 120 can be expelled. The interface between the Ge layer 120 and the insulating layer 104, the top surface of the Ge layer 120, and the gettering sink within the Ge layer 120 are each an example of a defect trapping section that traps crystal defects that can move within the Ge layer 120.

The defect trapping section may be a top surface or an interface with the crystal, or may be a physical flaw. The defect trapping section may be arranged at a distance that enables movement of the crystal defects for the temperature and duration conditions of the annealing.

The Ge layer 120 is an example of a seed layer that provides a seed surface for the functional layer. Another example of a seed surface includes SiₓGe₁₋ₓ, where 0≦x<1. The annealing may be performed in two stages including a high-temperature annealing for 2 to 10 minutes at a temperature between 800° C. and 900° C., and low-temperature annealing for 2 to 10 minutes at a temperature between 680° C. and 780° C.

The Ge layer 120 may be selectively crystal-grown in the open region. The Ge layer 120 can be formed using methods such as CVD and MBE (Molecular Beam Epitaxy), for example. The raw material gas may be GeH₄. The Ge layer 120 can be formed using the CVD method with a pressure no less than 0.1 Pa and no greater than 100 Pa. Therefore, the growth rate of the Ge layer 120 is not affected by the area of the open region. As a result, the uniformity of the thickness of the Ge layer 120 can be improved, for example. In this case, the deposition of Ge crystals on the top surface of the insulating layer 104 can be restricted.

The Ge layer 120 may be formed using the CVD method in an atmosphere that includes raw material gas containing halogen atoms. The gas containing halogen atoms may be a hydrogen chloride gas or a chlorine gas. As a result, the deposition of Ge crystals on the top surface of the insulating layer 104 is restricted even when the Ge layer 120 is formed using the CVD method with a pressure of no less than 100 Pa.

The present embodiment describes an example in which the Ge layer 120 is formed contacting the top surface of the Si wafer 102, but the present invention is not limited to this. For example, another layer may be arranged between the Ge layer 120 and the Si wafer 102. This other layer may be a single layer or may include a plurality of layers.

The Ge layer 120 may be formed according to the following steps. First, a seed crystal is formed at a low temperature. The seed crystal may be SiₓGe₁₋ₓ, where 0≦x<1. The temperature at which the seed crystal is grown may be no less than 330° C. and no greater than 450° C. After this, the temperature of the Si wafer 102 on which the seed crystal is formed is raised to a prescribed temperature, after which the Ge layer 120 may be formed.

The GaAs layer 124 is epitaxially grown on the Ge layer 120. The GaAs layer 124 can he grown directly on the Ge layer 120. The GaAs layer can be formed on the Ge layer 120 with another layer therebetween.

The GaAs layer 124 may have an arithmetic mean roughness value (sometimes referred to hereinafter as the “Ra value”) that is no greater than 0.02 μm, preferably no greater than 0.01 μm. As a result, a high-performance device can be formed using the GaAs layer 124. Here, the Ra value is an indicator of the surface roughness, and can be calculated according to JIS B0601-2001. The Ra value can be obtained by dividing (i) the area between a roughness curve and a central line over a prescribed length by (ii) the measured length.

The growth rate of the GaAs layer 124 may be no greater than 300 nm/min, preferably no greater than 200 nm/min, and more preferably no greater than 60 nm/min. As a result, the Ra value of the GaAs layer 124 can be held at 0.02 μm or less. The growth rate of the GaAs layer 124 may be no less than 1 nm/min, preferably no less than 5 nm/min. As a result, a high-quality GaAs layer 124 can be achieved without sacrificing the rate of production. For example, the GaAs layer 124 may be crystal-grown with a rate between 1 nm/min and 300 nm/min, inclusive.

The present embodiment describes an example in which a GaAs layer 124 is formed on the top surface of a Ge layer 120, but the present invention is not limited to this. For example, an intermediate layer may be arranged between the Ge layer 120 and the GaAs layer 124. This intermediate layer may be a single layer or may include a plurality of layers. The intermediate layer may be formed at a temperature no greater than 600° C., preferably no greater than 550° C. As a result, the crystallinity of the GaAs layer 124 can he improved. The intermediate layer may be formed at a temperature no less than 400° C. The intermediate layer may be formed at a temperature between 400° C. and 600° C., inclusive. As a result, the crystallinity of the GaAs layer 124 can be improved. The intermediate layer may be a GaAs layer formed at a temperature no greater than 600° C., preferably no greater than 550° C.

The GaAs layer 124 may be formed according to the following steps. First, the intermediate layer is formed on the top surface of the Ge layer 120. The temperature at which the intermediate layer is grown may be no greater than 600° C. After this, the temperature of the Si wafer 102 on which the intermediate layer is formed is raised to a prescribed temperature, after which the GaAs layer 124 may be formed.

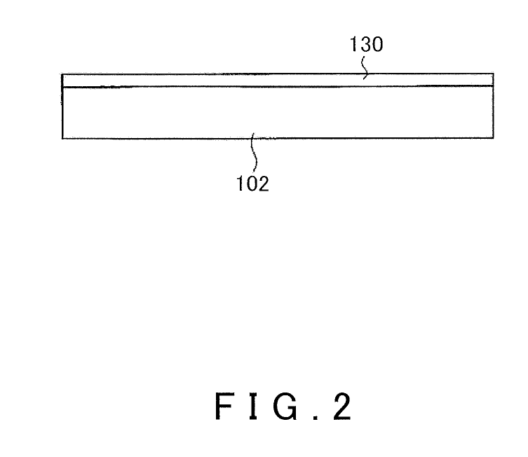

FIGS. 2 to 6 are exemplary cross-sectional views of steps for manufacturing the semiconductor wafer 101. As shown in FIG. 2, the Si wafer 102 is prepared and silicon oxide layer 130, for example, is formed on the top surface of the Si wafer 102 to serve as the insulating layer. The silicon oxide layer 130 may be formed using the thermal oxidation method. The thickness of the silicon oxide layer 130 may be 1 μm.

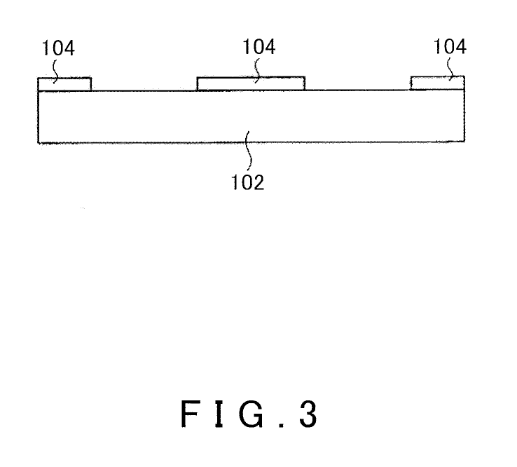

As shown in FIG. 3, the silicon oxide layer 130 is patterned to form the insulating layer 104. By forming the insulating layer 104, the open region is also formed. The patterning may he achieved by photolithography, for example.

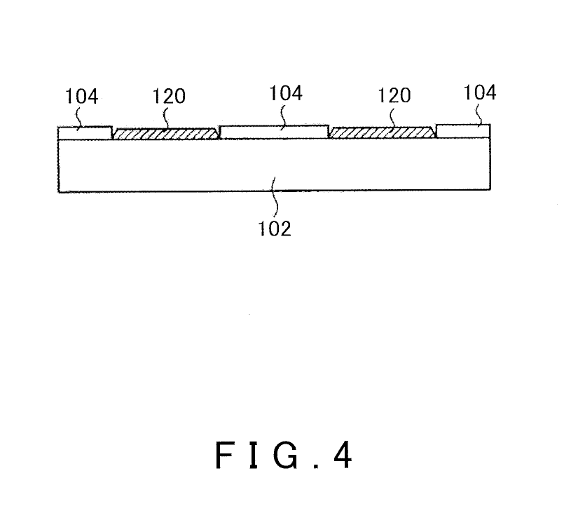

As shown in FIG. 4, the Ge layer 120 is epitaxially grown in the open region. The epitaxial growth of the Ge layer 120 is performed as described below. First, an Si wafer 102 is placed in a CVD reaction chamber that can create an ultra-high vacuum low-pressure state and a raw material gas is introduced to the CVD reaction chamber, and the wafer is heated to a first temperature at which the raw material gas can thermally decompose.

A first epitaxial layer made of Ge is then selectively formed on the portion of the Si wafer 102 that is exposed by the open region. Next, the raw material gas is introduced to the CVD reaction chamber and the wafer is heated to a second temperature, which is higher than the first temperature, to form a second epitaxial layer made of Ge on the first epitaxial layer. The raw material gas may be GeH₄.

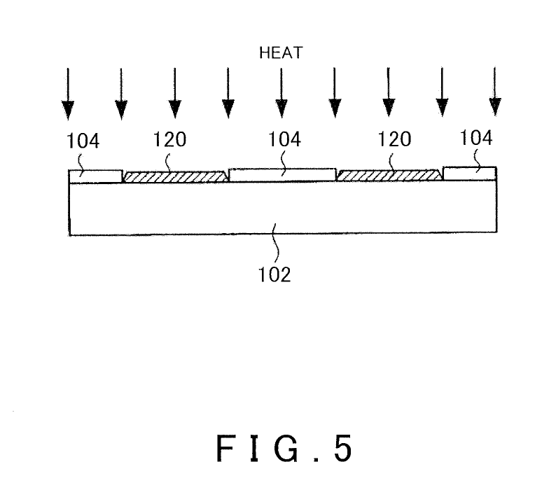

As shown in FIG. 5, the epitaxially grown Ge layer 120 is thermally annealed. The thermal annealing is performed as described below. First, the first and second epitaxial layers are annealed at a third temperature that is lower than the melting point of Ge.

Next, the first and second epitaxial layers are annealed at a fourth temperature that is lower than the third temperature. In this way, a Ge layer 120 that is selectively epitaxially grown in the open region is formed. This two-stage annealing can be repeated multiple times.

The conditions for the annealing at the third temperature may be a temperature of 900° C. and a duration of 10 minutes. The conditions for the annealing at the fourth temperature may be a temperature of 780° C. and a duration of 10 minutes. The number of repetitions of this annealing may be 10. After the annealing, a gas including phosphine may be supplied to the top surface of the Ge layer 120 for surface processing.

In the present embodiment, the two-stage annealing is repeated multiple times after the Ge layer 120 is epitaxially grown. Therefore, the crystal defects that are present during the epitaxial growing can be moved to the edges of the Ge layer 120 by the annealing, and the density of the crystal defects in the Ge layer 120 can then be reduced to a very low level by expelling the moved crystal defects from the edges of the Ge layer 120. As a result, the defects caused by wafer materials of an epitaxial thin film to be formed later, for example, can be decreased, thereby improving the capabilities of the electronic elements formed on the GaAs layer 124. Furthermore, even if there is a type of thin film that cannot be crystal-grown directly on a silicon wafer due to lattice mismatching, a high quality crystal thin film can be formed having a Ge layer 120 with superior crystallinity as the wafer material.

Before growing the GaAs layer 124, the annealed Ge layer 120 can be held at a high temperature and a gas containing PH₃ (phosphine) can be supplied to the top surface of the Ge layer 120. By processing the top surface of the Ge layer 120 with PH₃, the crystal quality of the GaAs layer 124 grown thereon can he increased. A desirable processing temperature range is from 500° C. to 900° C., inclusive. Higher or lower temperatures are undesirable because the effect of the processing does not appear at temperatures below 500° C. and the properties of the Ge layer 120 changes at temperatures above 900° C. A more preferable processing temperature range is from 600° C. to 800° C., inclusive.

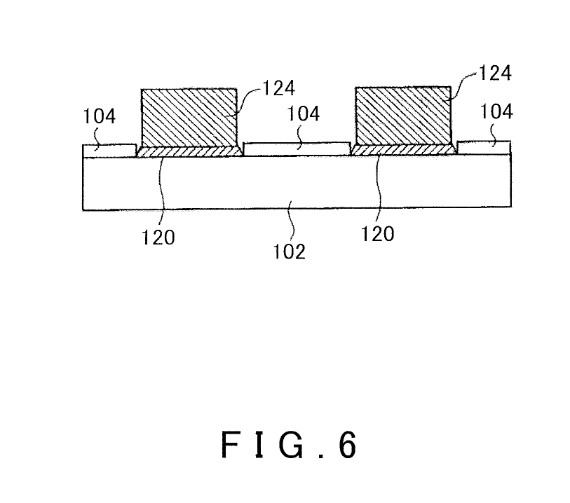

As shown in FIG. 6, the GaAs layers 124 can be epitaxially grown by introducing a raw material gas for forming the GaAs layers into the CVD reaction chamber so that the raw material gas contacts the surface processed Ge layers 120. The epitaxial growth of the GaAs layers 124 can he achieved using methods such as MOCVD and MBE, for example. The raw material gas may be TM-Ga (trimethylgallium), AsH₃ (arsine), or some other gas. The growth temperature may be between 600° C. and 650° C. Since the insulating layer 104 inhibits growth during the epitaxial growth of the GaAs layers 124, the GaAs layers 124 are not formed on the insulating layer 104.

After this, if electronic elements such as the HBTs are formed on the GaAs layers 124 using a known method, the semiconductor wafer 101 shown in FIG. 1 can be obtained. With the method described above, the semiconductor wafer 101 of the present embodiment was manufactured. In the semiconductor wafer 101 of the present embodiment, Ge layers 120 are selectively grown in open regions defined by the insulating layer 104, and a semiconductor wafer 101 having GaAs layers 124 with good crystallinity can be obtained by repeatedly applying two-stage annealing to the Ge layers 120 to improve the crystallinity of the Ge layers 120. Since the semiconductor wafer 101 uses an Si wafer 102, the semiconductor wafer 101 can be manufactured at a low cost and the heat generated by the electronic elements formed on the GaAs layers 124 can be efficiently released.

### Embodiments

### First Embodiment

A semiconductor wafer including an Si wafer 102, an insulating layer 104, Ge layers 120, and GaAs layers 124 was formed, and a relationship between (i) the growth rate of the crystal grown within an opening formed by the insulating layer 104 and (ii) the size of a covering region and the size of the opening was examined. The experimentation involved changing the bottom shape of the opening and the planar shape of the covering region formed on the insulating layer 104 and measuring the thickness of a GaAs layer 124 that is grown over a prescribed time.

First, the covering region and the opening were formed on the top surface of the Si wafer 102 according to the following steps. A commercial single-crystal Si wafer was used as an example of the Si wafer 102. The thermal oxidation method was used to form an SiO₂ layer on the top surface of the Si wafer 102, as an example of the insulating layer 104.

The SiO₂ layer was etched to be a prescribed size. More than two SiO₂ layers of the prescribed size were formed. At this time, the planar shapes of the SiO₂ layers having the prescribed size were designed to each be squares of the same size. Etching was then used to form an opening with a prescribed size in the center of each square SiO₂ layer. At this time, the square SiO₂ layers were each designed such that the center of the SiO₂ layer matches the center of the opening. One opening was formed in each square SiO₂ layer. In this Specification, the length of a side of a square SiO₂ layer may be referred to as the “length of a side of the covering region.”

Next, the CVD method was used to selectively grow Ge layers 120 within the openings. The raw material gas was GeH₄. The flow rate and deposition time of the raw material gas were each set to a prescribed value. Next, the MOCVD method was used to crystal-grow the GaAs layers 124. The GaAs layers 124 were epitaxially grown on the top surfaces of the Ge layers 120 within the opening under conditions of 620° C. and 8 MPa. The raw material gas used was trimethylgallium and arsine. The flow rate and deposition time of the raw material gas were each set to a prescribed value.

After formation of the GaAs layers 124, the thickness of the GaAs layers 124 was measured. The thickness of the GaAs layers 124 was calculated by using a surface profiler (Surface Profiler P-10 manufactured by KLA Teneor) to measure the thickness at three points of each GaAs layer 124 and calculating the average thickness of these three points. At this time, the standard deviation of the thickness at the three points was also calculated. This thickness may instead be calculated by using a transmission electron microscope or a scanning electron microscope to directly measure the thickness at three points of the GaAs layer 124 according to a cross-section observation method, and calculating the average thickness of these three points.

As a result of the above steps, the thickness of the GaAs layer 124 was measured while changing the bottom shape of the opening when the length of a side of the covering region is set to be 50 μm, 100 μm, 200 μm, 300 μm, 400 μm, and 500 μm, respectively. Experimentation was performed for three bottom shapes of the opening, which are a square in which a side is 10 μm, a square in which a side is 20 μm, and a rectangle in which a short side is 30 μm and a long side is 40 μm.

When the length of a side of the covering region is 500 μm, a plurality of the square SiO₂ layers are formed integrally. When this happens, it is not the case that covering regions with a side length of 500 μm are arranged at intervals of 500 μm, but for ease of explanation, the explanation will deal with a case where the length of a side of each covering region is 500 μm. Furthermore, for ease of explanation, the distance between adjacent covering regions is treated as being 0 μm.

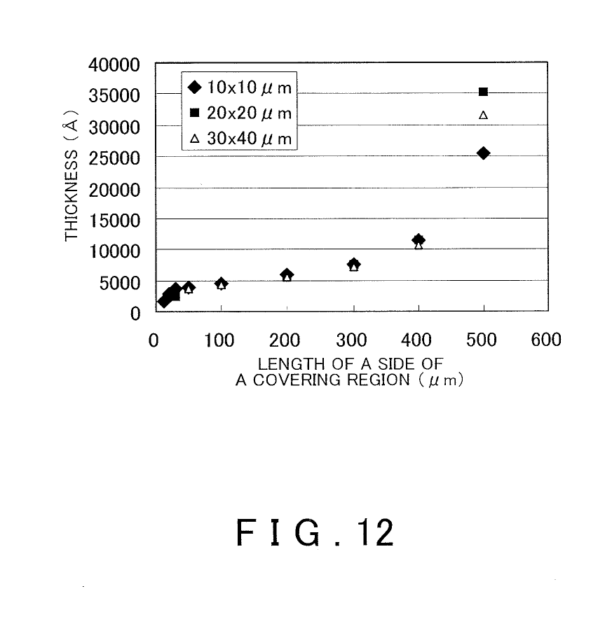

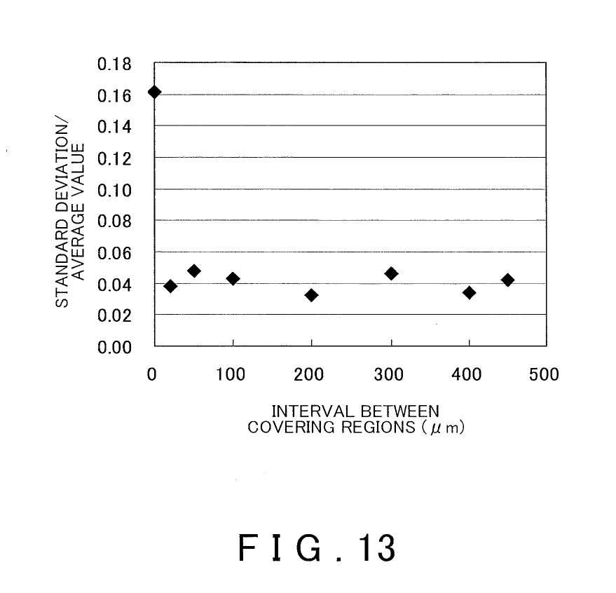

The experimental results for the First Embodiment are shown in FIGS. 12 and 13. FIG. 12 shows an average value of the thickness of each GaAs layer 124 formed in the First Embodiment. FIG. 13 shows a variation coefficient of the thickness of each GaAs layer 124 formed in the First Embodiment.

FIG. 12 shows the relationship between the growth rate of the GaAs layer 124 and the sizes of the covering region and the opening. In FIG. 12, the vertical axis represents the thickness (Å) of the GaAs layer 124 grown during a prescribed time, and the horizontal axis represents the length (μm) of a side of a covering region. In the present embodiment, the thickness of the GaAs layer 124 is the thickness grown during a prescribed time, and so an approximate value of the growth rate of the GaAs layer 124 can be calculated by dividing this thickness by the prescribed time.

In FIG. 12, the rhomboid plotting points represent experimental data obtained when the bottom shape of the opening is a square in which a side is 10 μm, and the square plotting points represent experimental data obtained when the bottom shape of the opening is a square in which a side is 20 μm. Furthermore, the triangular plotting points represent experimental data obtained when the bottom shape of the opening is a rectangle in which a long side is 40 μm and a short side is 30 μm.

Based on FIG. 12, it is understood that the growth rate monotonically increases when the size of the covering region increases. Furthermore, it is understood that, when the length of a side of a covering region is 400 μm or less, the growth rate increases almost linearly, and so there is little variation due to the bottom shape of the opening. On the other hand, it is understood that, when the length of a side of a covering region is 500 μm, the growth rate increases suddenly relative to the cases in which the length of a side of a covering region is 400 μm or less, and so there is increased variation due to the bottom shape of the opening.

FIG. 13 shows a relationship between the variation coefficient of’ the growth rate of the GaAs layer 124 and the distance between adjacent covering regions. Here, the variation coefficient is a ratio of the standard deviation to the average value, and can be calculated by dividing the standard deviation of the thickness at the three measurement points by the average value of this thickness. In FIG. 13, the vertical axis represents the variation coefficient of the thickness (Å) of the GaAs layer 124 grown during a prescribed time, and the horizontal axis represents the distance (μm) between adjacent covering regions. FIG. 13 shows experimental data for cases in which the distance between adjacent covering regions is 0 μm, 20 μm, 50 μm, 100 μm, 200 μm, 300 μm, 400 μm, and 450 μm, respectively. In FIG. 13, the rhomboid plotting points represent experimental data obtained when the bottom shape of the opening is a square in which a side is 10 μm.

In FIG. 13, the experimental data for cases in which the distance between adjacent covering regions is 0 μm, 100 μm, 200 μm, 300 μm, 400 μm, and 450 μm, corresponds respectively to the experimental data in FIG. 12 for the cases in which the length of a side of a covering region is 500 μm, 400 μm, 300 μm, 200 μm, 100 μm, and 50 μm. The data concerning eases in which the distance between adjacent covering regions is 20 μm and 50 μm can each be obtained in the same way as the other experimental data by measuring the thickness of the GaAs layer 124 in cases where the length of a side of a covering region is 480 μm and 450 μm, respectively.

Based on FIG. 13, it is understood that, in comparison with the case in which the distance between adjacent covering regions is 0 μm, setting this distance to be 20 μm results in a much more stable growth rate for the GaAs layer 124. Based on the above results, it is understood that the growth rate of the crystal grown within the opening can be stabilized when adjacent covering regions are separated by even a small amount. Furthermore, it is understood that the growth rate of the crystal can be stabilized by arranging regions in which crystal growth occurs between adjacent covering regions. Even if the distance between adjacent covering regions is 0 μm, variations in the growth rate of the crystal can be restricted by arranging a plurality of openings at uniform intervals.

### Second Embodiment

Semiconductor wafers were manufactured, using the same steps as in the First Embodiment, and were respectively designed such that the length of a side of a covering region was 200 μm, 500 μm, 700 μm, 1000 μm, 1500 μm, 2000 μm, 3000 μm, and 4250 μm, and the thickness of the GaAs layer 124 within the opening of each semiconductor wafer was measured. In the present embodiment, the SiO₂ layers were formed such that a plurality of SiO₂ layers having the same size were formed on each Si wafer 102. Furthermore, the SiO₂ layers were formed to he separated from each other. In the same way as in the First Embodiment, experimentation was performed for three bottom shapes of the opening, which are a square in which a side is 10 μm, a square in which a side is 20 μm, and a rectangle in which a short side is 30 μm and a long side is 40 μm. The growth conditions for the Ge layer 120 and the GaAs layer 124 were the same as those in the First Embodiment.

### Third Embodiment

The amount of trimethylgallium supplied was cut in half to approximately halve the growth rate of the GaAs layer 124, but otherwise, the same processes and conditions as in the Second Embodiment were used and the thickness of the GaAs layer 124 formed within each opening was measured. In the Third Embodiment, experimentation was performed for cases in which the bottom shape of the opening is a square in which length of a side is 10 μm while the length of a side of a covering region was respectively set to 200 μm, 500 μm, 1000 μm, 2000 μm, 3000 μm, and 4250 μm.

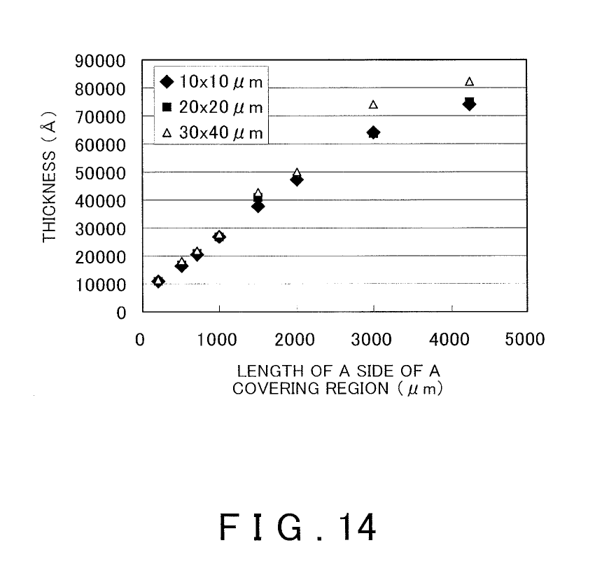

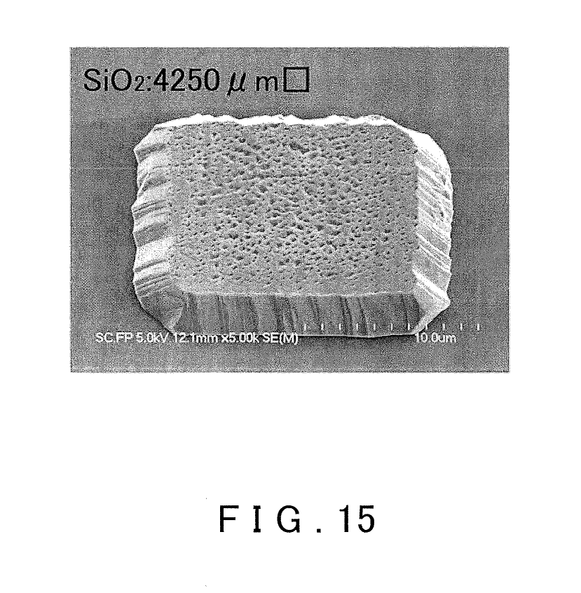

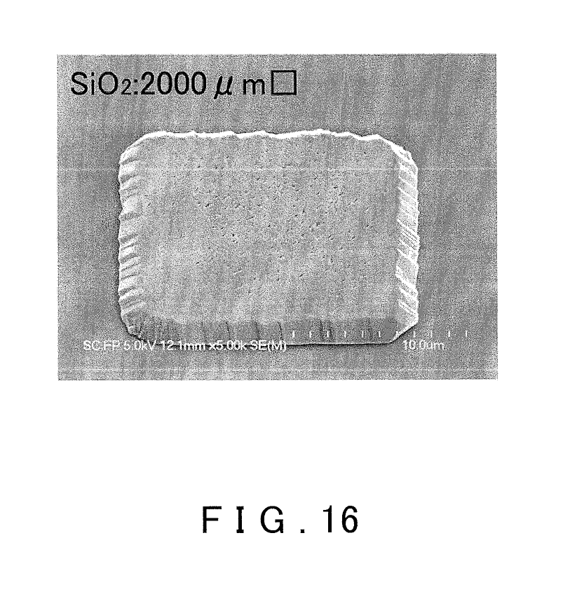

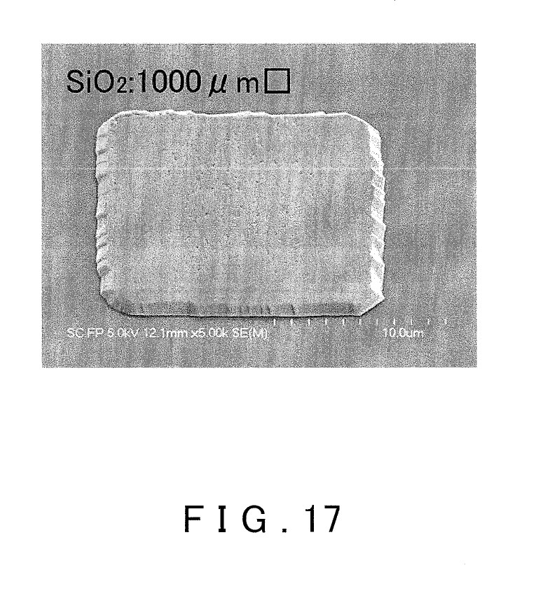

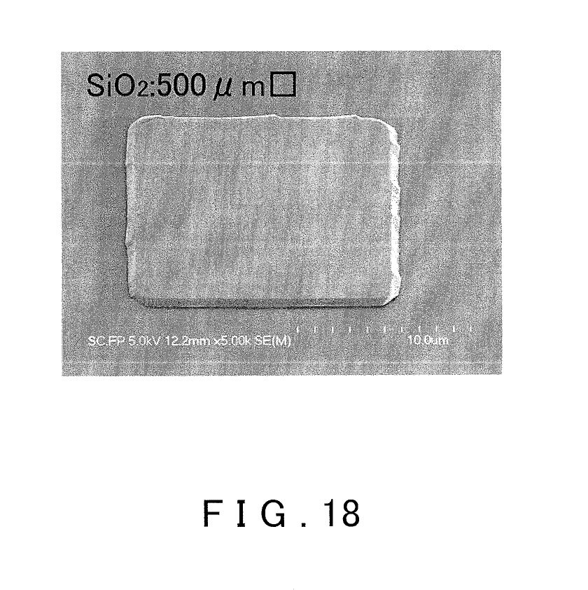

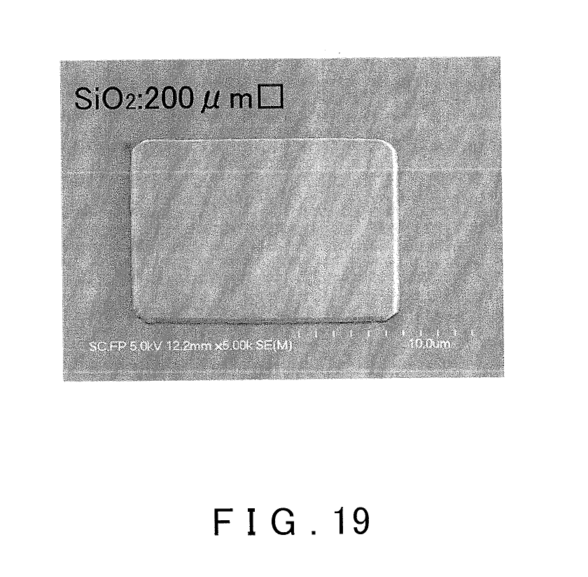

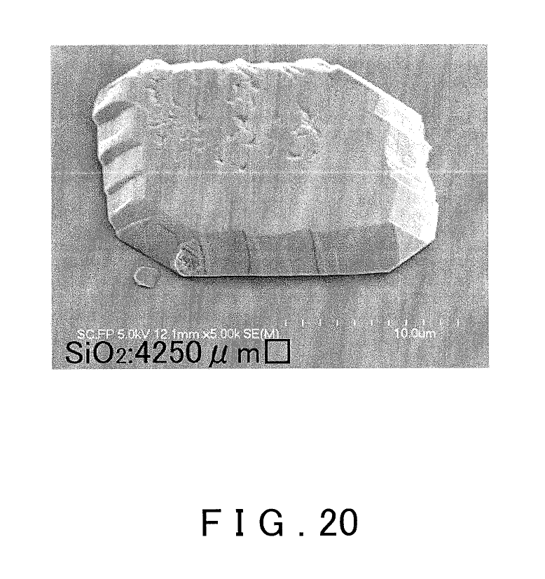

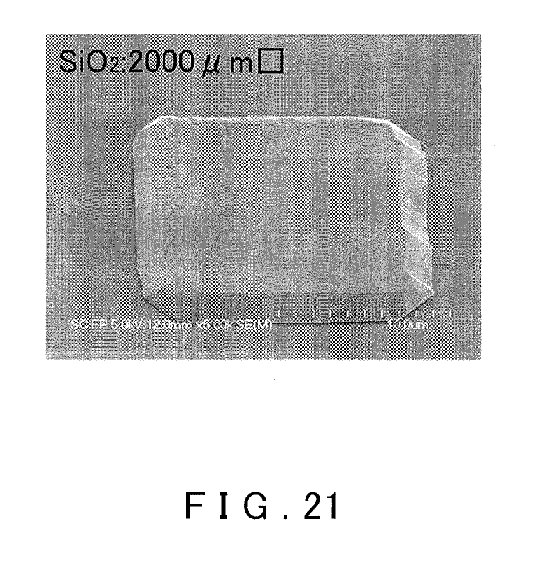

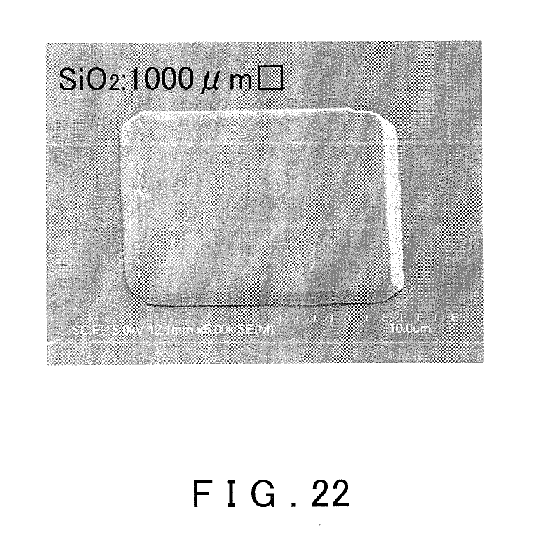

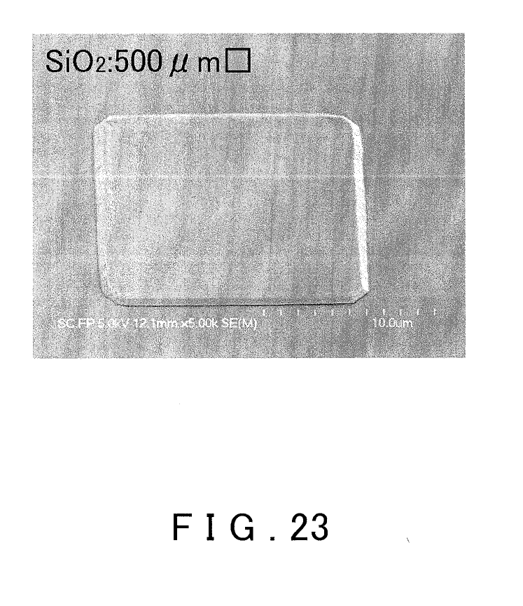

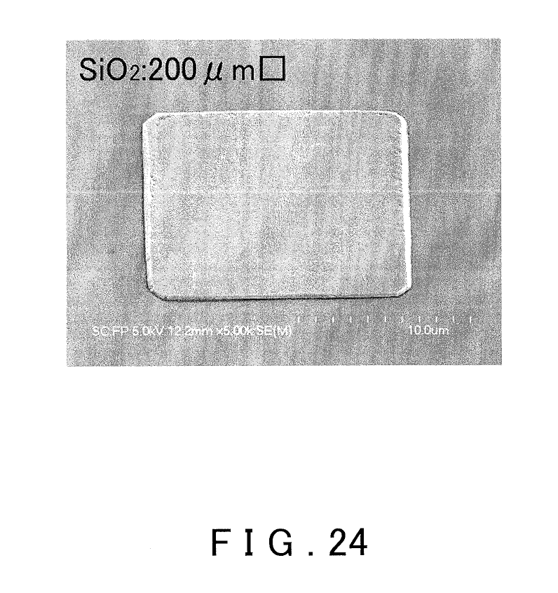

The experimental results for the Second and Third Embodiments are shown in FIGS. 14 to 24 and Table 1. FIG. 14 shows an average value of the thickness of each GaAs layer 124 formed in the Second Embodiment. FIGS. 15 to 19 show electron microscope images of each GaAs layer 124 formed in the Second Embodiment. FIGS. 20 to 24 show electron microscope images of each GaAs layer 124 formed in the Third Embodiment. Table 1 shows an Ra value and a growth rate of each GaAs layer 124 formed in the Second and Third Embodiments.

FIG. 14 shows the relationship between the growth rate of the GaAs layer 124 and the sizes of the covering region and the opening. In FIG. 14, the vertical axis represents the thickness of the GaAs layer 124 grown during a prescribed time, and the horizontal axis represents the length (μm) of a side of a covering, region. In the present embodiment, the thickness of the GaAs layer 124 is the thickness grown during a prescribed time, and so an approximate value of the growth rate of the GaAs layer 124 can he calculated by dividing this thickness by the prescribed time.

In FIG. 14, the rhomboid plotting points represent experimental data obtained when the bottom shape of the opening is a square in which a side is 10 μm, and the square plotting points represent experimental data obtained when the bottom shape of the opening is a square in which a side is 20 μm. Furthermore, the triangular plotting points represent experimental data obtained when the bottom shape of the opening is a rectangle in which a long side is 40 μm and a short side is 30 μm.

Based on FIG. 14, it is understood that the growth rate increases stably until the size of a covering region increases to a point at which the length of a side of the covering region reaches 4250 μm. Based on the results shown in FIGS. 12 and 14, it is understood that the growth rate of the crystal grown within the opening can be stabilized when adjacent covering regions are separated by even a small amount. Furthermore, it is understood that the growth rate of the crystal can be stabilized by arranging regions in which crystal growth occurs between adjacent covering regions.

FIGS. 15 to 19 show results obtained by using an electron microscope to observe the top surface of each GaAs layer 124 formed in the Second Embodiment. FIGS. 15 to 19 respectively show results obtained when the length of a side of a covering region is 4250 μm, 2000 μm, 1000 μm, 500 μm, and 200 μm. Based on FIGS. 15 to 19, it is understood that an increase in the size of the covering regions leads to worsening of the surface condition of the GaAs layer 124.

FIGS. 20 to 24 show results obtained by using an electron microscope to observe the top surface of each GaAs layer 124 formed in the Third Embodiment. FIGS. 20 to 24 respectively show results obtained when the length of a side of a covering region is 4250 μm, 2000 μm, 1000 μm, 500 μm, and 200 μm. Based on FIGS. 20 to 24, it is understood that an increase in the size of the covering regions leads to worsening of the surface condition of the GaAs layer 124. Furthermore, it is understood that, in comparison to the results obtained for the Second Embodiment, the surface condition of the GaAs layers 124 was improved.

Table 1 shows an Ra value (μm) and a growth rate (Å/min) of each GaAs layer 124 formed in the Second and Third Embodiments. The thickness of each GaAs layer 124 was measured by a surface profiler. The Ra value was calculated based on the results observed using a laser microscope device. Based on Table 1, it is understood that lower growth rate for the GaAs layer 124 results in lower surface roughness. Furthermore, it is understood that the Ra value is no greater than 0.02 μm when the growth rate of the GaAs layer 124 is no greater than 300 nm/min.

TABLE 1

| | SECOND EMBODIMENT | | THIRD EMBODIMENT | |
|---|---|---|---|---|
| COVERING REGION | GROWTH RATE | Ra VALUE | GROWTH RATE | Ra VALUE |
| SIDE LENGTH [μm] | [Å/min] | [μm] | [Å/min] | [μm] |
| 200 | 526 | 0.006 | 286 | 0.003 |
| 500 | 789 | 0.008 | 442 | 0.003 |
| 1000 | 1216 | 0.012 | 692 | 0.005 |
| 2000 | 2147 | 0.017 | 1264 | 0.007 |
| 3000 | 3002 | 0.02 | 1831 | 0.008 |
| 4250 | 3477 | 0.044 | 2190 | 0.015 |

### Fourth Embodiment

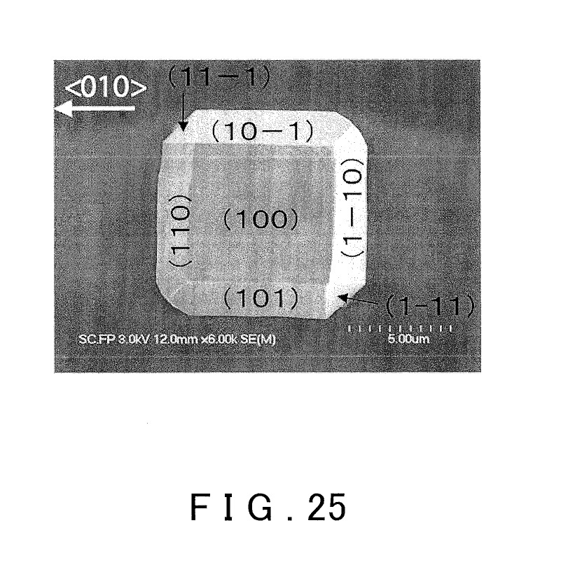

In the same way as in the First Embodiment, a semiconductor wafer including an Si wafer 102, an insulating layer 104, Ge layers 120, and GaAs layers 124 was manufactured. In the present embodiment, the insulating layer 104 was formed on the (100) surface of the top surface of the Si wafer 102. FIGS. 25 to 27 show electron microscope images of the top surface of the GaAs crystal formed on the above semiconductor wafer.

FIG. 25 shows results obtained when the GaAs crystal was grown within an opening that was arranged such that a side of the bottom shape of the opening was substantially parallel to the <010> direction of the Si water 102. In the present embodiment, the planar shape of the covering region was a square in which each side had a length of 300 μm. The bottom shape of the opening was a square in which a side is 10 μm. In FIG. 25, the arrow represents the direction <010>. As shown in FIG. 25, the obtained crystal had an ordered shape.

Based on FIG. 25, it is understood that the four side surfaces of the GaAs crystal are the (10-1) surface; the (1-10) surface, the (101) surface, and the (110) surface. Furthermore, it is understood from FIG. 25 that there is a (11-1) surface at the upper left corner of the GaAs crystal and a (1-11) surface at the lower right corner of the GaAs crystal. The (11-1) surface and the (1-11) surface are equivalent to a (-1-1-1) surface, and these are stable surfaces.

It is further understood from FIG. 25 that such stable surfaces are not present at the upper right corner or the lower left corner of the GaAs crystal. For example, in FIG. 25, even though a (111) surface may be present at the bottom left corner, this (111) surface is not present in this ease. This is believed to he because the bottom left corner is sandwiched between the (110) surface and the (101) surface, which are more stable than the (111) surface.

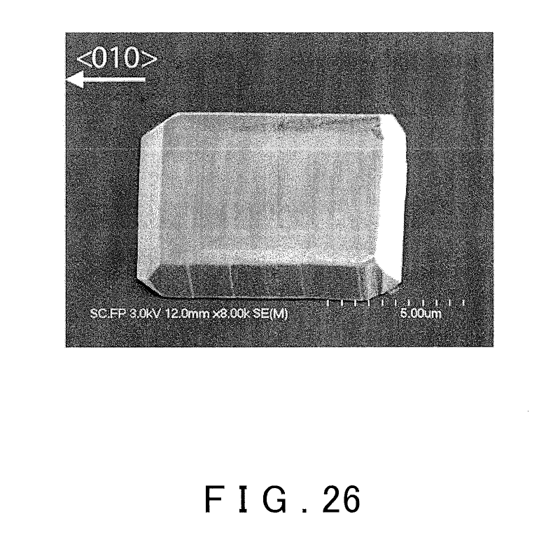

FIG. 26 shows results obtained when the GaAs crystal was grown within an opening that was arranged such that a side of the bottom shape of the opening was substantially parallel to the <010> direction of the Si wafer 102. FIG. 26 shows results as seen from above at a 45° angle. In the present embodiment, the planar shape of the covering region was a square in which each side had a length of 50 μm. The bottom shape of the opening was a square in which the length of a side is 10 μm. In FIG. 26, the arrow represents the direction <010>. As shown in FIG. 26, the obtained crystal had an ordered shape.

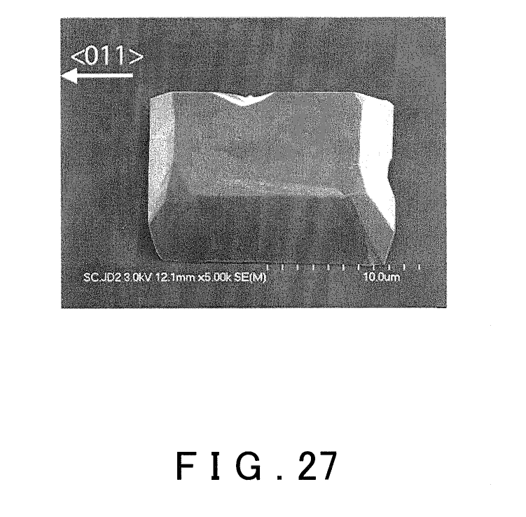

FIG. 27 shows results obtained when the GaAs crystal was grown within an opening that was arranged such that a side of the bottom shape of the opening was substantially parallel to the <011> direction of the Si wafer 102. In the present embodiment, the planar shape of the covering region was a square in which each side had a length of 400 μm. The bottom shape of the opening was a square in which the length of a side is 10 μm. In FIG. 27, the arrow represents the direction <011>. As shown in FIG. 27, the obtained crystal had a shape that was more disordered than the shapes shown in FIGS. 25 and 26. This is believed to be because, as a result of the relatively unstable (111) surface appearing on the side surface of the GaAs crystal, disorder occurred in the shape of the crystal.

### Fifth Embodiment

In the same way as in the First Embodiment, a semiconductor water including an Si wafer 102, an insulating layer 104, a Ge layer 120, and a GaAs layer 124 was manufactured. In the present embodiment, intermediate layer was formed between the Ge layer 120 and the GaAs layer 124. In the present embodiment, the planar shape of the covering region was a square in which each side had a length of 200 μm. The bottom shape of the opening was a square in which a side is 10 μm. The CVD method was used to form the Ge layer 120 with a thickness of 850 nm within the opening, and then annealing was performed at 800° C.

After annealing the Ge layer 120, the temperature of the Si wafer 102 on which the Ge layer 120 is formed was set to 550° C. and the intermediate layer was formed using the MOCVD method. The intermediate layer was grown using trimethylgallium and arsine as the raw material gas. The thickness of the intermediate layer was 30 nm. Next, the Si wafer 102 on which the intermediate layer is formed was raised to a temperature of 640° C., after which the MOCVD method was used to form the GaAs layer 124. The thickness of the GaAs layer was 500 nm. Other conditions were the same as those used when manufacturing the semiconductor wafer of the First Embodiment.

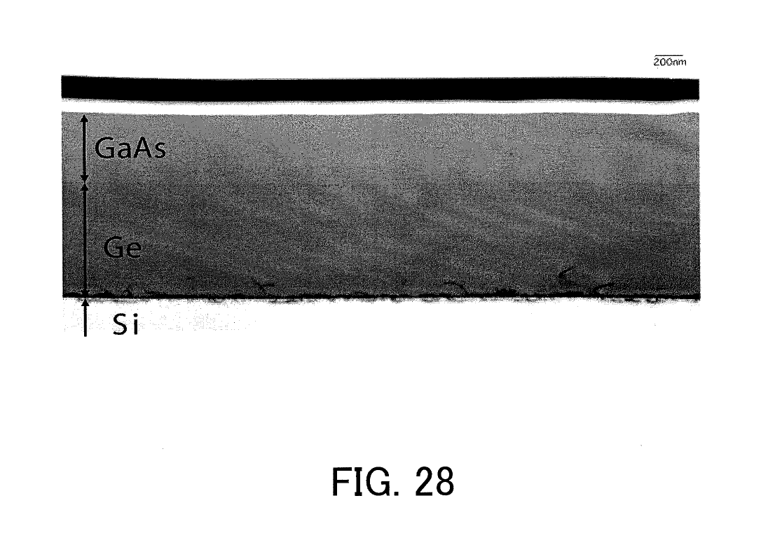

FIG. 28 shows results obtained by viewing a cross-section of the manufactured semiconductor wafer with a transmission electron microscope. As shown in FIG. 28, dislocation was not observed in the Ge layer 120 or the GaAs layer. Therefore, it is understood that, by adopting the configuration described above, a high-quality Ge layer and a compound semiconductor layer that lattice matches or pseudo-lattice matches with the Ge layer can be formed on the Si wafer.

### Sixth Embodiment

In the same way as in the Fifth Embodiment, a semiconductor wafer including an Si wafer 102, an insulating layer 104, a Ge layer 120, an intermediate layer, and a GaAs layer 124 was manufactured, and an HBT element structure was then formed using the resulting semiconductor wafer. The HBT element structure was manufactured using the following steps. First, in the same way as in the Fifth Embodiment, a semiconductor wafer was manufactured. In the present embodiment, the planar shape of the covering region was a square in which each side had a length of 50 μm. The bottom shape of the opening was a square in which a side is 20 μm. Other conditions were the same as those used when manufacturing the semiconductor wafer of the Fifth Embodiment.

Next, the MOCVD method was used to form a semiconductor layer on the top surface of the GaAs layer of the semiconductor wafer. As a result, an HBT element structure was formed that included, in the stated order, the Si wafer 102, a Ge layer 120 with a thickness of 850 nm, an intermediate layer with a thickness of 30 nm, an undoped GaAs layer with a thickness of 500 nm, an n-type GaAs layer with a thickness of 300 nm, an n-type InGaP layer with a thickness of 20 nm, an n-type GaAs layer with a thickness of 3 nm, a GaAs layer with a thickness of 300 nm, a p-type GaAs layer with a thickness of 50 nm, an n-type InGaP layer with a thickness of 20 nm, an n-type GaAs layer with a thickness of 120 nm, and an n-type InGaAs layer with a thickness of 60 nm. Electrodes were arranged on the resulting HBT element structure to form an HBT element, which is an example of an electronic element or an electronic device. In the semiconductor layers described above, Si was used as the n-type impurity. In the semiconductor layers described above, C was used as the p-type impurity.

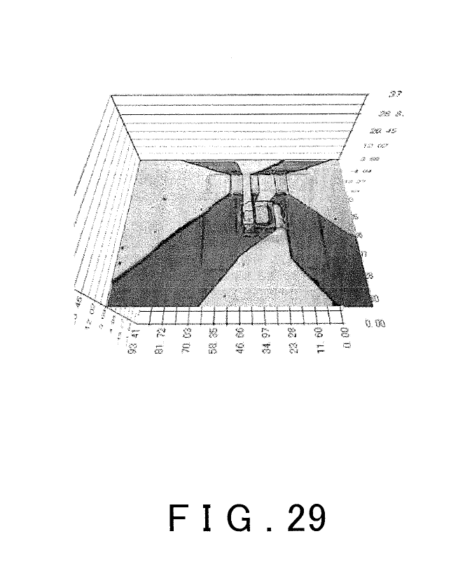

FIG. 29 shows a laser microscope image of a manufactured HBT element. In FIG. 29, the light gray portions represent the electrodes. Based on FIG. 29, it is understood that three electrodes are lined up in the open region arranged near the center of the square covering region. The three electrodes are respectively, in order from the left side of FIG. 29, a base electrode., an emitter electrode, and a collector electrode of the HBT element. Upon measuring the electrical characteristics of this HBT element, it was confirmed that operation as a transistor was possible. Furthermore, upon observing a cross-section of the HBT clement with a transmission electron microscope, no dislocation was seen.

### Seventh Embodiment

In the same manner as the Sixth Embodiment, three HBT elements having the same structure as the HBT clement of the Sixth Embodiment were manufactured. The three HBT elements were connected in parallel. In the present embodiment, the planar shape of each covering region was a rectangle in which a long side had a length of 100 μm and a short side had a length of 50 μm. Three openings were formed within these covering regions. The bottom shape of each opening was a square in which a side is 15 μm. Other conditions were the same as those used when manufacturing the HBT element of the Sixth Embodiment.

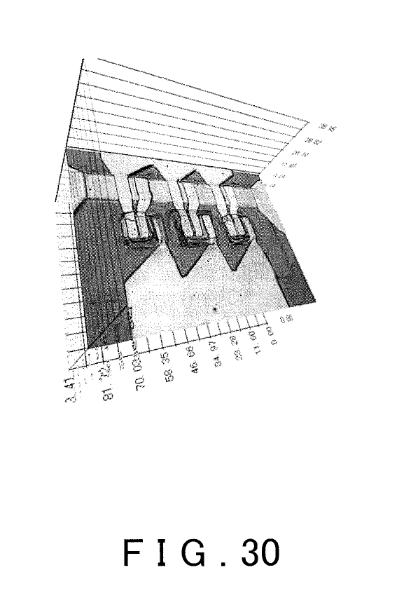

FIG. 30 shows a laser microscope image of a manufactured HBT element. In FIG. 30, the light gray portions represent the electrodes. Based on FIG. 30, it is understood that the three HBT elements are connected in parallel. Upon measuring the electrical characteristics of this electronic element, it was confirmed that operation as a transistor was possible.

### Eighth Embodiment

HBT elements were manufactured with different bottom areas for the openings, and the relationship between the bottom area of an opening and the electric characteristics of the resulting HBT element was examined. HBT elements were manufactured in the same manner as the Sixth Embodiment. The base sheet resistance value R_{b} (Ω/□) and and the current gain β were measured as the electrical characteristics of the HBT elements. The current gain β was calculated by dividing the value of the collector current by the value of the base current. Experimentation was performed for HBT elements having five bottom shapes of the opening, which were a square in which a side is 20 μm, a rectangle in which a short side is 20 μm and a long side is 40 μm, a square in which a side is 30 μm, a rectangle in which a short side is 30 μm and a long side is 40 μm, and a rectangle in which a short side is 20 μm and a long side is 80 μm.

When the bottom shape of the opening was a square, the opening was formed such that one of two orthogonal sides of the bottom shape of the opening was parallel to the direction <010> of the Si wafer 102, and the other of the two orthogonal sides is parallel to the direction <001> of the Si wafer 102. When the bottom shape of the opening was a rectangle, the opening was formed such that a long side of the bottom shape of the opening was parallel to the direction <010> of the Si wafer 102, and a short side was parallel to the direction <001> of the Si wafer 102. Experimentation was performed mainly for cases in which the planar shape of the covering region was a square in which a side had a length of 300 μm.

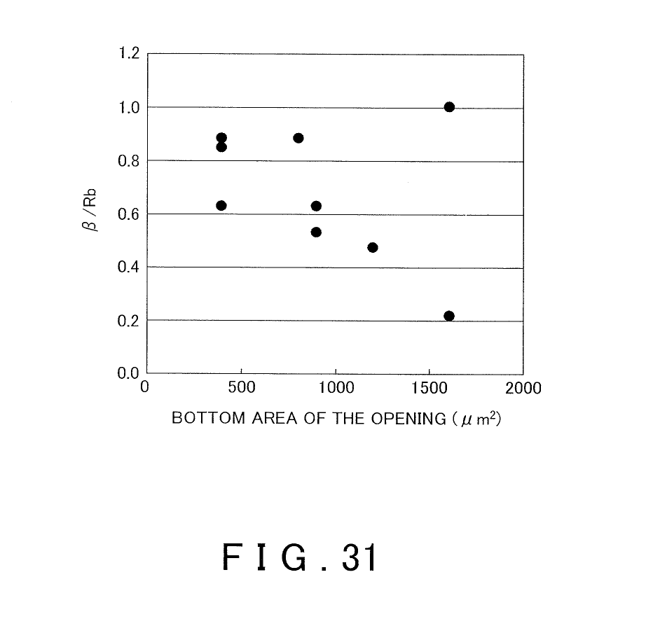

FIG. 31 shows a relationship between the bottom area (μm²) of the opening and a ratio of the current gain β to the base sheet resistance value R_{b} of the HBT elements described above. In FIG. 31, the vertical axis represents a value obtained by dividing the current gain β by the base sheet resistance value R_{b}, and the horizontal axis represents the bottom area of the opening. FIG. 31 does not show the current gain β, but high values from 70 to 100 were obtained for the current gain. On the other hand, the current gain β was no greater than 10 when the HBT elements were formed by forming the same HBT element structures over the entire surface of the Si wafer 102.

Therefore, it is understood that a device with favorable electrical characteristics can be manufactured by forming the HBT element structures locally on the top surface of the Si wafer 102. It is understood that a device with particularly good electrical characteristics can be manufactured when a side of the bottom shape of the opening is no greater than 80 μm or when the bottom area of the opening is no greater than 1600 μm².

Based on FIG. 31, it is understood that the variation in the ratio of the current gain β to the base sheet resistance value R_{b} is smaller when the bottom area of the opening is 900 μm² or less, than when the bottom area of the opening is 1600 μm² or more. Therefore, it is understood that the device described above can be manufactured with good yield when a side of the bottom shape of the opening is no greater than 40 μm or when the bottom area of the opening is no greater than 900 μm².

As described above, a semiconductor wafer was manufactured according to a method of manufacturing a semiconductor wafer including (i) forming an insulating layer on a single-crystal Si wafer, (ii) patterning the insulating layer to form an opening in the insulating layer exposing the wafer, (iii) placing the wafer, on which the insulating layer having the open region is formed, in a CVD reaction chamber that can create an ultra-high vacuum low-pressure state, (iv) introducing a raw material gas into the CVD reaction chamber and heating the wafer to a first temperature at which the raw material gas can thermally decompose, to selectively form a first epitaxial layer made of Ge on the portion of the wafer exposed by the opening, (v) introducing the raw material gas into the CVD reaction chamber and heating the wafer to a second temperature that is higher than the first temperature, to form a second epitaxial layer made of Ge on the first epitaxial layer, (vi) annealing the first and second epitaxial layers at a third temperature that is lower than the melting point of Ge, (vii) annealing the first and second epitaxial layers at a fourth temperature that is lower than the third temperature, (viii) supplying a gas containing phosphine to the top surface of a Ge layer, after the annealing is performed, to surface process the Ge layer, and (ix) introducing a raw material gas for Conning a GaAs layer into the CVD reaction chamber to epitaxially grow the GaAs layer by having the raw material gas contact the top surface of the surface-processed Ge layer.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

### INDUSTRIAL APPLICABILITY

A crystal thin film with good crystallinity can be formed on an inexpensive silicon wafer, and this crystal thin film can be used to form a semiconductor wafer, an electronic device, or the like.

1. A semiconductor wafer comprising:
a single-crystal Si wafer;
an insulating layer that has an open region and that is formed on the wafer;
a Ge layer that is epitaxially grown on the wafer in the open region; and
a GaAs layer that is epitaxially grown on the Ge layer, wherein
the Ge layer is formed by (i) placing the wafer in a CVD reaction chamber that can create an ultra-high vacuum low-pressure state, (ii) performing a first epitaxial growth at a first temperature at which raw material gas can thermally decompose, (iii) performing a second epitaxial growth at a second temperature that is higher than the first temperature, (iv) performing a first annealing, at a third temperature that is less than a melting point of Ge, on epitaxial layers formed by the first and second epitaxial growths, and (v) performing a second annealing at a fourth temperature that is lower than the third temperature.

2. The semiconductor wafer according to claim 1, wherein
the Ge layer is formed by repeating the first annealing and the second annealing a plurality of times.

3. The semiconductor wafer according to claim 1, wherein
the insulating layer is a silicon oxide layer.

4. A semiconductor wafer comprising:
a single-crystal Si wafer;
an insulating layer in which is formed an opening passing therethrough in a direction substantially perpendicular to a principal surface of the wafer, to expose the wafer;
a Ge layer that is crystal-grown on the wafer within the opening; and
a GaAs layer that is epitaxially grown on the Ge layer, wherein
the Ge layer is formed by (i) placing the wafer in a CVD reaction chamber that can create an ultra-high vacuum low-pressure state, (ii) performing a first epitaxial growth at a first temperature at which raw material gas can thermally decompose, (iii) performing a second epitaxial growth at a second temperature that is higher than the first temperature, (iv) performing a first annealing, at a third temperature that is less than a melting point of Ge, on epitaxial layers formed by the first and second epitaxial growths, and (v) performing a second annealing at a fourth temperature that is lower than the third temperature.

5. The semiconductor wafer according to claim 4, wherein
the Ge layer is formed by performing at least one of the first annealing and the second annealing in an atmosphere containing hydrogen.

6. The semiconductor wafer according to claim 4, wherein
the Ge layer is formed by being selectively crystal-grown within the opening using a CVD method including a raw material gas containing halogen atoms.

7. The semiconductor wafer according to claim 4, wherein
arithmetic mean roughness of the GaAs layer is no greater than 0.02 μm.

8. The semiconductor wafer according to claim 4, wherein
the insulating layer is a silicon oxide layer.

9. The semiconductor wafer according to any one of claim 4, wherein
the insulating layer includes a plurality of the openings, and
the semiconductor wafer further comprises an adsorbing section that adsorbs raw material of the GaAs layer more quickly than a top surface of the insulating layer and that is arranged between one of the openings and another opening adjacent to the one of the openings.

10. The semiconductor wafer according to claim 4, comprising:
a plurality of the insulating layers; and
an adsorbing section that adsorbs raw material of the GaAs layer more quickly than a top surface of any of the insulating layers and that is arranged between one of the insulating layers and another insulating layer that is adjacent to the one of the insulating layers.

11. The semiconductor wafer according to claim 9, wherein
the adsorbing section is a groove that reaches the wafer.

12. The semiconductor wafer according to claim 11, wherein width of the groove is between 20 μm and 500 μm, inclusive.

13. The semiconductor wafer according to claim 9, comprising a plurality or the adsorbing sections, wherein
the plurality of the adsorbing sections are arranged at uniform intervals.

14. The semiconductor wafer according to claim 4, wherein
bottom area of the opening is no greater than 1 mm².

15. The semiconductor wafer according to claim 14, wherein the bottom area of the opening is no greater than 1600 μm².

16. The semiconductor wafer according to claim 15, wherein the bottom area of the opening is no greater than 900 μm².

17. The semiconductor wafer according to claim 14, wherein
a bottom of the opening is shaped as a rectangle, and
a long side of the rectangle is no greater than 80 μm.

18. The semiconductor wafer according to claim 17, wherein
a bottom of the opening is shaped as a rectangle, and
a long side of the rectangle is no greater than 40 μm.

19. The semiconductor wafer according to claim 4, wherein
the principal surface of the wafer is a (100) surface,
a bottom of the opening is shaped as a square or a rectangle, and
at least one side of the square or the rectangle is substantially parallel to a direction selected from a group including a <010> direction, a <0-10> direction, a <001> direction, and a <00-1> direction on the principal surface.

20. The semiconductor wafer according to claim 4, wherein
the principal surface of the wafer is a (111) surface,
a bottom o the opening is shaped as a hexagon, and
at least one side of the hexagon is substantially parallel to a direction selected from a group including a <1-10> direction, a <-110> direction, a <0-11> direction, a <01-1> direction, a <10-1> direction, and a <-101> direction on the principal surface.

21. A method of manufacturing a semiconductor wafer comprising:
forming an insulating layer on a single-crystal Si wafer;
patterning the insulating layer to form an open region in the insulating layer that exposes the wafer;
placing the wafer, on which the insulating, layer having the open region is formed, in a CVD reaction chamber that can create an ultra-high vacuum low-pressure state;
introducing a raw material gas into the CVD reaction chamber and heating the wafer to a first temperature at which the raw material gas can thermally decompose, to selectively form a first epitaxial layer made of Ge on a portion of the wafer exposed by the open region;
introducing raw material gas into the CVD reaction chamber and heating the wafer to a second temperature that is higher than the first temperature, to form a second epitaxial layer made of Ge on the first epitaxial layer;
annealing the first and second epitaxial layers at a third temperature that is lower than a melting point of Ge;
annealing the first and second epitaxial layers at a fourth temperature that is lower than the third temperature;
supplying a gas containing phosphine to a top surface of a Ge layer, after the annealing is performed, to surface process the Ge layer; and
introducing a raw material gas for forming a GaAs layer into the CVD reaction chamber to epitaxially grow the GaAs layer on the top surface of the surface-processed Ge layer.

22. The method of manufacturing a semiconductor wafer according to claim 21, wherein
the annealing at the third temperature and the annealing at the fourth temperature are performed a plurality or times.

23. The method or manufacturing a semiconductor wafer according to claim 21, wherein
the insulating layer is a silicon oxide layer.

24. A method of manufacturing a semiconductor wafer comprising:
forming an insulating layer on a single-crystal Si wafer;
patterning the insulating layer to form an opening in the insulating layer that exposes the wafer;
placing the wafer, on which the insulating layer having the opening is formed, in a CVD reaction chamber that can create an ultra-high vacuum low-pressure state;
introducing a raw material gas into the CVD reaction chamber and heating the wafer to a first temperature at which the raw material gas can thermally decompose, to selectively form a first epitaxial layer made of Ge on a portion of the wafer exposed by the opening;
introducing raw material gas into the CVD reaction chamber and heating the wafer to a second temperature that is higher than the first temperature, to form a second epitaxial layer made of Ge on the first epitaxial layer;
annealing the first epitaxial layer and the second epitaxial layer at a third temperature that is lower than a melting point of Ge;
annealing the first epitaxial layer and the second epitaxial layer at a fourth temperature that is lower than the third temperature;
supplying a gas containing phosphine to a top surface of a Ge layer, after the annealing is performed, to surface process the Ge layer; and
introducing a raw material gas for forming a GaAs layer into the CVD reaction chamber to epitaxially grow the GaAs layer on the top surface of the surface-processed Ge layer.

25. The method of manufacturing a semiconductor wafer according to claim 24, wherein
at least one of the third temperature and the fourth temperature is greater than or equal to 680° C. and less than 900° C.

26. The method of manufacturing a semiconductor wafer according to claim 24, wherein
the annealing at the third temperature includes annealing the Ge layer in an atmosphere containing hydrogen.

27. The method of manufacturing a semiconductor wafer according to claim 24, wherein
the annealing at the fourth temperature includes annealing the Ge layer in an atmosphere containing hydrogen.

28. The method of manufacturing a semiconductor wafer according to claim 24, wherein
the selectively forming the first epitaxial layer made of Ge includes selectively crystal-growing the Ge layer in the opening according to a CVD method using a pressure between 0.1 Pa and 100 Pa, inclusive.

29. The method of manufacturing a semiconductor wafer according to claim 24, wherein
the selectively forming the second epitaxial layer made of Ge includes selectively crystal-growing the Ge layer in the opening according to a CVD method using a pressure between 0.1 Pa and 100 Pa, inclusive.

30. The method of manufacturing a semiconductor wafer according to claim 24, wherein
the selectively forming the first epitaxial layer made of Ge includes selectively crystal-growing the Ge layer in the opening according to a CVD method performed in an atmosphere that includes raw material gas containing halogen atoms.

31. The method of manufacturing a semiconductor wafer according to claim 24, wherein
the selectively forming the second epitaxial layer made of Ge includes selectively crystal-growing the Ge layer in the opening according to a CVD method performed in an atmosphere that includes raw material gas containing, halogen atoms.

32. The method of manufacturing a semiconductor wafer according to claim 24, wherein
the epitaxially growing the GaAs layer includes crystal-growing the GaAs layer with a growth rate no less than 1 nm/min and no greater than 300 nm/min.
